(19) United States
(12) Patent Application Publication
(10) Pub. No.: US 2019/0284089 A1
(43) Pub. Date: Sep. 19, 2019

(54) SOLAR CELL ELECTRODE CONDUCTIVE PASTE COMPOSITION, AND SOLAR CELL COMPRISING ELECTRODE MANUFACTURED BY USING SAME

(71) Applicant: LS-NIKKO COPPER INC., Ulsan (KR)

(72) Inventors: Tae Hyun JUN, Seongnam (KR); In Chul KIM, Yongin (KR); Min Soo KO, Seoul (KR); Hwa Young NOH, Hwaseong (KR); Mun Seok JANG, Seoul (KR); Chung Ho KIM, Namyangju (KR)

(21) Appl. No.: 16/463,812

(22) PCT Filed: Oct. 18, 2017
(86) PCT No.: PCT/KR2017/011514

§ 371 Date: May 23, 2019

(30) Foreign Application Priority Data
Nov. 24, 2016 (KR) 10-2016-0157586

(51) Int. Cl. C03C 8/18; H01L 31/0224; C03C 8/10; C03C 8/12; C03C 4/14; H01B 1/22; H01L 31/18

(52) U.S. Cl. CPC C03C 8/18; H01L 31/022425; C03C 8/10; C03C 8/12; C03C 2205/00; H01B 1/22; H01L 31/18; C03C 2204/00; C03C 4/14

(57) ABSTRACT

The present invention relates to a conductive paste composition for a solar cell electrode, including a conductive metal powder, a glass frit and an organic vehicle, wherein the glass frit has a specific composition that enables the formation of a side shape in which a surface slope, measured depending on the height relative to a wafer, increases and then decreases, and upon electrode formation using the conductive paste including such a glass frit, wetting characteristics and spreadability are improved such that the light-receiving area of a solar cell is enlarged, thus increasing short-circuit current, and contact resistance is also improved to thus increase a fill factor (FF), ultimately increasing the power generation efficiency of the solar cell.

### TECHNICAL FIELD

The present invention relates to a conductive paste composition for a solar cell electrode and a solar cell including an electrode manufactured using the same.

### BACKGROUND ART

Solar cells are semiconductor devices that convert solar energy into electrical energy, and typically have a p-n junction type, and the basic structure thereof is the same as a diode. FIG. 1 shows the configuration of a general solar cell device. The solar cell device is typically configured using a p-type silicon semiconductor substrate 10 having a thickness of 180 to 250 μm. An n-type impurity layer 20, having a thickness of 0.3 to 0.6 μm, is formed on the light-receiving surface of the silicon semiconductor substrate, and an antireflective film 30 and a front electrode 100 are formed thereon. A rear electrode 50 is also formed on the rear surface of the p-type silicon semiconductor substrate.

The front electrode 100 is formed by applying a conductive paste containing conductive particles of silver as a main component, a glass frit and an organic vehicle, which are mixed therewith, on the antireflective film 30 and then firing it, and the rear electrode 50 is formed by applying an aluminum paste composition comprising an aluminum powder, a glass frit and an organic vehicle through a screen-printing process or the like, followed by drying and then firing at a temperature of 660° C. (the melting point of aluminum) or higher. Aluminum is diffused into the p-type silicon semiconductor substrate at the time of firing, whereby an Al—Si alloy layer is formed between the rear electrode and the p-type silicon semiconductor substrate, and simultaneously a p+ layer 40 is formed as an impurity layer due to the diffusion of aluminum atoms. The presence of this p+ layer prevents the recombination of electrons, and thus a BSF (Back Surface Field) effect, which increases the collection efficiency of the generated carriers, is obtained. A rear silver electrode 60 may be further disposed under the rear aluminum electrode.

For the formation of metal electrodes on both surfaces of a silicon wafer, a process of forming an electrode, including printing a paste containing a metal powder and a glass frit in a screen-printing manner and then performing drying and firing, is currently mainly used in a crystalline solar cell mass-production line, and the characteristics of the solar cell are achieved through a high-temperature sintering process. In particular, during the high-temperature process of sintering the front electrode at 750° C. or higher, burn-out of organic materials such as an organic vehicle, contact resistance formation through melting, expansion and contraction of inorganic materials such as conductive particles and glass frit, and short-circuit current (Isc) formation due to the ensured light-receiving area may result.

Meanwhile, in the front electrode during the firing, the antireflective film is etched through the oxidation-reduction reaction of the glass frit powder, the conductive metal crystal grains are precipitated in a form in which the conductive powder crystal in the glass frit powder is precipitated on the substrate interface, and the precipitated metal crystal grains are known not only to serve as a crosslinkage between the bulk front electrode and the silicon substrate, but also to exhibit contact due to direct adhesion with the bulk electrode or a tunneling effect depending on the thickness of the glass frit powder.

Conventionally, in order to improve the contact resistance between an electrode and a wafer having a high sheet resistance of 80 Ω/sq or more, as disclosed in Patent Document 1 (U.S. Pat. No. 8,497,420), TeO₂ and PbO are contained in excess amounts of 35 to 70 mol % and 30 to 65 mol %, respectively, thereby lowering the glass transition temperature (Tg) of the glass frit to about 220 to 290° C. However, when the glass transition temperature is lowered, the glass frit is melted at a relatively low temperature during the high-temperature sintering process, thereby accelerating wetting to thus spread the electrode, which is undesirable.

The line width of the metal pattern in the front electrode of the solar cell has to be decreased in order to minimize light loss due to absorption into or reflection from the metal electrode, and the height of the pattern has to be increased for electrode resistance. Hence, when the glass transition temperature of the glass frit is low, wetting characteristics become good, and thus contact resistance becomes good, but spreading of the electrode becomes large, and thus short-circuit current (Isc) deteriorates, undesirably decreasing the efficiency of the solar cell.

### DISCLOSURE

### Technical Problem

Accordingly, the present invention has been made keeping in mind the problems encountered in the related art, and an objective of the present invention is to provide a conductive paste composition for a solar cell electrode, in which the wetting characteristics and reactivity of a glass frit may be adjusted upon high-temperature sintering, thus ensuring electrode contact resistance of a solar cell, and also electrode spreading may be controlled to thereby enlarge the light-receiving area of the solar cell, ultimately attaining high cell efficiency through increasing short-circuit current (Isc).

However, the objectives of the present invention are not limited to the foregoing, and other objectives which are not mentioned herein will be able to be clearly understood by those skilled in the art from the following description.

### Technical Solution

The present invention provides a conductive paste composition for a solar cell electrode, comprising a conductive metal powder, a glass frit and an organic vehicle.

Here, when a pellet having a diameter of 6.8 mm and a depth of 2 mm is made using the glass frit, placed on a wafer and then sintered at a temperature of 500 to 900° C. for 20 to 30 sec, a wetting diameter ratio calculated using Equation 1 below is 180% or less and an aspect ratio calculated using Equation 2 below is 0.15 or more.

Wetting diameter ratio (%)=(diameter after sintering/diameter before sintering)*100 [Equation 1]

Aspect ratio=height of pellet from wafer/diameter of pellet [Equation 2]

Furthermore, when the side shape of the sintered pellet is represented as the slope of the tangent line of the pellet surface to the wafer depending on the height relative to the wafer,

the sintered pellet shows a side shape having a concave section where the slope of the tangent line increases, an inflection section where the slope of the tangent line increases and then decreases, and a convex section where the slope of the tangent line decreases with an increase in the height relative to the wafer.

### Advantageous Effects

The present invention is capable of providing a conductive paste composition for a solar cell electrode comprising a conductive metal powder, a glass frit and an organic vehicle, in which the glass frit has a specific composition that enables the formation of a side shape in which the surface slope, measured depending on the height relative to the wafer, increases and then decreases. When an electrode is formed using the conductive paste including such a glass frit, wetting characteristics and spreadability are improved, and thus the light-receiving area of the solar cell is enlarged, and contact resistance is improved and thus short-circuit current (Isc) is increased, thereby increasing the power generation efficiency of the solar cell.

More specifically, when an electrode is formed on a wafer using the conductive paste according to the present invention, the area of the portion thereof close to the wafer is enlarged, thus improving wetting characteristics, that is, contact resistance, and also, spreadability is decreased at the portion thereof far from the wafer, thereby improving series resistance to ultimately increase the conversion efficiency of the manufactured solar cell.

In addition, the present invention is capable of providing a conductive paste including, as a Pb—Te-based glass frit containing lead (Pb) and tellurium (Te) to thus be excellent in lowering contact resistance, a glass frit having a composition capable of improving both contact resistance (wetting characteristics) and spreadability. Specifically, the present invention is directed to a conductive paste for a solar cell electrode, including a glass frit having a composition capable of forming an electrode having low contact resistance by securely fixing the conductive metal on the substrate through etching of the antireflective film upon high-temperature sintering for electrode formation and also having a high aspect ratio (of line height to line width) by decreasing electrode spreadability.

More specifically, according to the present invention, PbO and Te₂O are used in certain amounts, thus improving contact resistance, and also, in order to solve problems related to an increase in spreadability, Bi₂O₃ is contained in a certain amount, thus improving spreadability. Furthermore, an alkaline metal oxide is contained in a certain amount, thus improving both contact resistance and spreadability.

Moreover, the conductive paste according to the present invention can be applied to crystalline solar cells (P-type, N-type), PESC (Passivated Emitter Solar Cell), PERC (Passivated Emitter and Rear Cell), PERL (Passivated Emitter Real Locally Diffused) structures and also to modified printing processes such as double printing, dual printing, etc.

### DESCRIPTION OF DRAWINGS

FIG. 1 shows the configuration of a solar cell device;

FIGS. 2 to 4 show images before and after firing of pellets of Example of the present invention and Comparative Examples;

FIG. 5 shows the slope of the tangent line depending on the height of the pellet surface in Example of the present invention and Comparative Example; and

FIGS. 6 to 8 show the electrode pattern images formed using the conductive pastes of Example of the present invention and Comparative Examples.

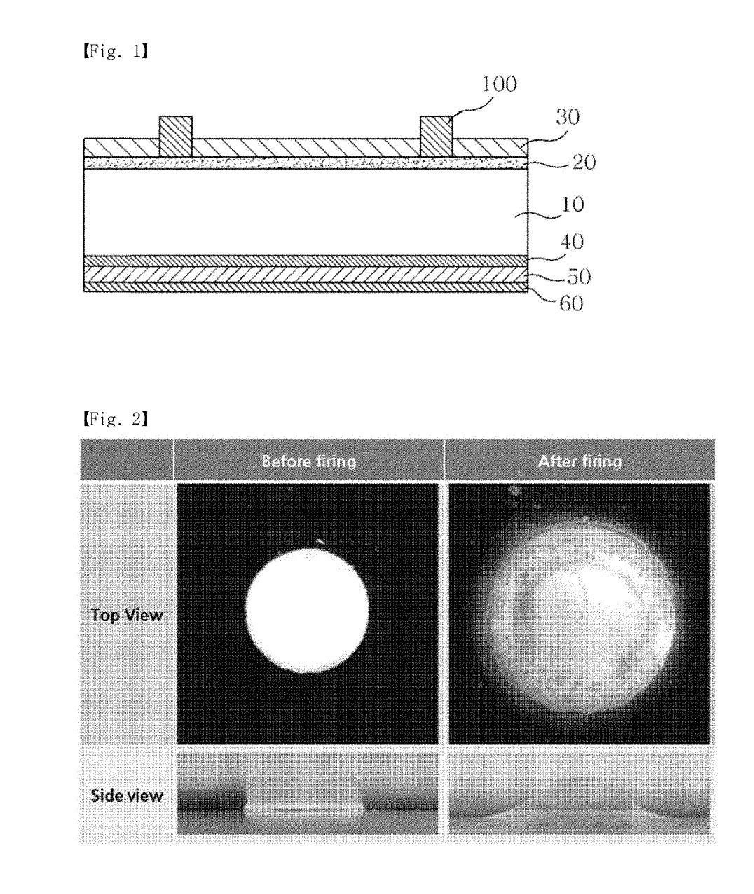

### MODE FOR INVENTION

In the following description of the present invention, the terms used herein are merely intended to describe specific embodiments and are not to be construed as limiting the scope of the present invention, which is defined by the appended claims. Unless otherwise defined, all technical or scientific terms used herein have the same meanings as those typically understood by persons having ordinary knowledge in the art to which the present invention belongs.

Unless otherwise stated, the terms “comprise”, “comprises” and “comprising” are used to designate the presence of an object, a step or groups of objects and steps described in the specification and claims, and should be understood as not excluding the presence or additional possibility of inclusion of any other objects, steps or groups of objects or steps.

Unless otherwise noted, various embodiments of the present invention may be combined with other embodiments. In particular, any feature that is said to be preferable or favorable may be combined with any other features said to be preferable or favorable. Hereinafter, a description will be given of embodiments of the present invention and effects thereof with reference to the appended drawings.

The present invention pertains to a conductive paste composition for a solar cell electrode, comprising a conductive metal powder, a glass frit and an organic vehicle, in which the glass frit has a specific composition that improves wetting characteristics and reactivity upon high-temperature sintering and also improves spreadability.

Individual components thereof are described in detail below.

<Conductive Metal Powder>

As a conductive metal powder, a silver powder, a copper powder, a nickel powder, an aluminum powder, etc. may be used, and the front electrode may be mainly formed of a silver powder, and the rear electrode may be mainly formed of an aluminum powder. For the sake of convenience, a conductive metal material is described using a silver powder as an example thereof. The following description is equally applicable to other metal powders.

The silver powder is preferably a pure silver powder, and other examples thereof may include a silver-coating complex powder having a silver layer on at least a surface thereof, an alloy composed mainly of silver, etc. Also, silver may be used in combination with another metal powder. For example, aluminum, gold, palladium, copper, nickel, and the like may be used. The silver powder may have an average particle size of 0.1 to 10 μm, and preferably has an average particle size of 0.5 to 5 μm considering the ease of formation of a paste and density upon firing, and the shape thereof may be at least one of a spherical shape, an acicular shape, a planar shape, and an indeterminate shape. The silver powder may be used in a mixture of two or more powders having different average particle diameters, particle size distributions and shapes. Taking into consideration the thickness and line resistance of an electrode formed upon printing, the silver powder is preferably used in an amount of 70 to 98 wt % based on the total weight of the conductive paste composition for an electrode.

<Glass Frit>

A glass frit is melted upon high-temperature sintering, and thus densification of the metal powder is induced, and moreover, an interfacial reaction with an antireflective film may occur to thereby etch the antireflective film so that the conductive metal is fixed onto the substrate, which is an oxidation-reduction reaction in which some elements are reduced and generated as byproducts.

According to the present invention, the glass frit is a Pb—Te—Bi-Alkali-based glass frit which contains lead (Pb) and tellurium (Te) to thus be excellent in lowering contact resistance, thereby providing a glass frit composition capable of improving both contact resistance (wetting characteristics) and spreadability. Specifically, the glass frit composition is capable of forming an electrode having low contact resistance by securely fixing the conductive metal on the substrate through etching of the antireflective film upon high-temperature sintering for electrode formation, and also having a high aspect ratio (of line height to line width) by decreasing electrode spreading.

More specifically, a conventional Pb—Te-based glass frit contains 30 mol % or more of lead oxide (PbO) and 35 mol % of tellurium oxide (Te₂O) to realize superior contact resistance, and is lowered in glass transition temperature and is thus melted at a low temperature, thereby improving contact resistance, but spreadability may increase, which is undesirable. Hence, in order to solve these problems, in the present invention, PbO and Te₂O are used in certain amounts to thus improve contact resistance, and Bi₂O₃ is contained in a certain amount to thus improve spreadability. Furthermore, an alkali metal oxide having high reactivity may be used in a certain amount, thereby effectively improving both contact resistance and spreadability. An additional inorganic additive may be added to form a net structure of the glass frit, thus ensuring and controlling the properties of the glass frit.

More specifically, in the components and amounts of the glass frit according to the present invention, 15 to 29 mol % of PbO, 15 to 34 mol % of TeO₂, and 10 to 24 mol % of Bi₂O₃ are contained on an oxide basis, and also, as alkali metal oxides, 3 to 12 mol % of Li₂O, 3 to 10 mol % of Na₂O and 3 to 10 mol % of K₂O are contained, and as additional inorganic additives, 20 mol % or less of SiO₂, 5 mol % or less of ZnO, 5 mol % or less of Al₂O₃, and 5 mol % or less of TiO₂ may optionally be further contained, thus increasing short-circuit current (Isc) and conversion efficiency (Eff).

Preferably, 20 to 29 mol % of PbO, 25 to 34 mol % of TeO₂, and 10 to 20 mol % of Bi₂O₃ are contained, and also, as alkali metal oxides, 3 to 10 mol % of Li₂O, 3 to 8 mol % of Na₂O, and 3 to 8 mol % of K₂O are contained, and as additional inorganic additives, 15 mol % or less of SiO₂, 3 mol % or less of ZnO, 3 mol % or less of Al₂O₃, and 3 mol % or less of TiO₂ may optionally be further included.

More preferably, 25 to 29 mol % of PbO, 30 to 34 mol % of TeO₂, and 15 to 20 mol % of Bi₂O₃ are contained, and also, as alkali metal oxides, 4 to 8 mol % of Li₂O, 4 to 7 mol % of Na₂O, and 4 to 7 mol % of K₂O are contained, and as additional inorganic additives, 10 mol % or less of SiO₂, 2 mol % or less of ZnO, 2 mol % or less of Al₂O₃, and 2 mol % or less of TiO₂ may optionally be further included.

According to the present invention, the glass frit is configured such that, despite the relatively low amounts of Pb and Te, which greatly affect an improvement in contact resistance, Bi₂O₃ is contained in a certain amount to thus solve problems in which spreadability is increased, and an alkali metal oxide having high reactivity is contained in a certain amount, whereby a pellet having a certain shape is manufactured using such a glass frit to thus improve both contact resistance and spreadability, which may be supported by the Examples and Test Examples to be described later.

In particular, reactivity with the antireflective film may increase by means of the alkali metal contained in a certain amount in the glass frit, thereby ensuring sufficient contact resistance for a short melting time. Also, since the reaction is completed within a short time, a bleeding phenomenon may be alleviated by reducing the time taken for the glass frit to spread.

The glass transition temperature (Tg) of the glass frit having the composition according to the present invention is 200 to 300° C. The glass frit according to the present invention has a low glass transition temperature of 300° C. or less, thus increasing melting uniformity and cell characteristic uniformity. Furthermore, superior contact characteristics may be ensured even upon rapid firing, and may be optimized for a solar cell having high sheet resistance (90 to 120 Ω/sq). When these components are combined in the above amounts, an increase in the line width of the electrode is prevented and superior contact resistance is ensured at high sheet resistance, resulting in superior short-circuit current characteristics.

If the amounts of PbO and TeO₂ are too high, environmental consequences are too great, and viscosity is excessively decreased upon melting, undesirably increasing the line width of the electrode upon firing. Hence, PbO is preferably contained within the above range in the glass frit.

Also, the glass frit may have an average particle diameter of 0.5 to 10 μm, and may be used by mixing a variety of particles having different average particle diameters. Preferably, at least one glass frit has an average particle diameter (D50) of 1 μm to 5 μm, and more preferably 1 μm to 3 μm. Thereby, reactivity upon firing becomes excellent, and an increase in the line width of the electrode may be reduced.

The amount of the glass frit is preferably 1 to 15 wt % based on the total weight of the conductive paste composition. If the amount thereof is less than 1 wt %, incomplete firing may occur and electrical resistivity may increase. On the other hand, if the amount thereof exceeds 15 wt %, the glass content in the sintered body of the silver powder may become too large and moreover, electrical resistivity may increase. Preferably, the amount of the glass frit is 1 to 10 wt %, and more preferably 1 to 5 wt %.

As parameters showing the effect of improving spreadability in the glass frit having the composition according to the present invention, there are a wetting diameter ratio (%), which is the ratio of the diameter after sintering to the diameter before sintering, as shown in Equation 1 below, and an aspect ratio, which is the ratio of the height to the width after sintering, as shown in Equation 2 below.

Wetting diameter ratio (%)=(diameter after sintering/diameter before sintering)*100 [Equation 1]

Aspect ratio=height/width [Equation 2]

Upon sintering using the conductive paste including the glass frit having the composition according to the present invention, a wetting diameter ratio (%) is 180% or less. If the wetting diameter ratio (%) exceeds 180%, spreadability is so great that the light-receiving area is reduced during the manufacture of the electrode of the solar cell, undesirably deteriorating power generation efficiency. More specifically, the wetting diameter ratio is 140 to 170%.

Also, upon sintering using the glass frit having the composition according to the present invention, an aspect ratio is 0.15 or more. If the aspect ratio is less than 0.15, the spreadability is so great that sufficient electrode height is not ensured during the manufacture of the electrode of the solar cell, undesirably increasing resistance and thus deteriorating power generation efficiency. Preferably, the aspect ratio is 0.16 or more, and more preferably 0.16 to 0.18.

The sintering conditions for measuring the wetting diameter ratio and the aspect ratio are the same as the sintering conditions for forming the electrode pattern. More specifically, a pellet having a diameter of 6.8 mm and a depth of 2 mm was made using the glass frit of the present invention, placed on a wafer and then sintered at a temperature of 500 to 900° C. for 20 to 30 sec, after which the diameter and the height thereof were measured to calculate the wetting diameter ratio (%) and the aspect ratio.

Also, when the side shape of the pellet, obtained by sintering the pellet under the above sintering conditions, is represented as the slope of the tangent line of the surface thereof to the wafer depending on the height relative to the wafer, the pellet sintered using the glass frit having the composition according to the present invention shows a side shape having a concave section where the slope of the tangent line increases, an inflection section where the slope of the tangent line increases and then decreases, and a convex section where the slope of the tangent line decreases with an increase in the height relative to the wafer.

More specifically, when the position of the pellet sintered using the glass frit having the composition according to the present invention depending on the height from the wafer is set to the range of 0% to 100%, the concave section is formed at a 0% to 40% position, the inflection section is formed at a 30% to 70% position, and the convex section is formed at a 70% to 100% position.

Also, the pellet sintered using the glass frit having the composition according to the present invention has a shape configured such that the average slope of the tangent line increases and then decreases with an increase in the position, in which the average slope of the tangent line in the concave section is 10 to 30°, the slope of the tangent line in the inflection section is 30 to 50°, and the slope of the tangent line in the convex section is 10 to 30°.

<Organic Vehicle>

The organic vehicle is not particularly limited, but may include an organic binder, a solvent, and the like. A solvent may sometimes be omitted. The amount of the organic vehicle is not particularly limited, but is preferably 1 to 20 wt % based on the total weight of the conductive paste composition for an electrode.

The organic vehicle is used to maintain the uniformly mixed state of metal powder and glass frit. For example, when conductive paste is applied onto a substrate through screen printing, the conductive paste is made homogenous, thus suppressing the blur and flow of the printed pattern, and moreover, properties that facilitate discharge of the conductive paste from the screen plate and separation of the plate are obtained.

The binder used in the conductive paste composition for an electrode according to the embodiment of the present invention is not particularly limited, but examples thereof may include a cellulose ester compound such as cellulose acetate, cellulose acetate butyrate and the like, a cellulose ether compound such as ethyl cellulose, methyl cellulose, hydroxypropyl cellulose, hydroxyethyl cellulose, hydroxypropylmethyl cellulose, hydroxyethylmethyl cellulose and the like, an acrylic compound such as polyacrylamide, polymethacrylate, polymethylmethacrylate, polyethylmethacrylate and the like, and a vinyl compound such as polyvinyl butyral, polyvinyl acetate, polyvinyl alcohol, and the like. At least one of these binders may be selected and used.

As the solvent used for the dilution of the composition, at least one selected from among alpha-terpineol, Texanol, dioctyl phthalate, dibutyl phthalate, cyclohexane, hexane, toluene, benzyl alcohol, dioxane, diethylene glycol, ethylene glycol monobutyl ether, ethylene glycol monobutyl ether acetate, diethylene glycol monobutyl ether, diethylene glycol monobutyl ether acetate, and the like may be used.

<Other Additives>

The conductive paste composition according to the present invention may further contain, as necessary, a typically known additive, for example, a dispersant, a plasticizer, a viscosity modifier, a surfactant, an oxidizing agent, a metal oxide, a metal organic compound and the like.

In addition, the present invention pertains to a method of forming an electrode for a solar cell, in which the conductive paste is applied on a substrate, dried and fired, and to a solar cell electrode manufactured by the method. Here, a substrate, a printing process, a drying process and a firing process useful in conventional methods for manufacturing solar cells may be applied, with the exception that the conductive paste including the glass frit having the composition above is used in the method of forming a solar cell electrode according to the present invention. For example, the substrate may be a silicon wafer.

When an electrode is formed using the conductive paste according to the present invention, wetting characteristics and spreadability may be improved, whereby the light-receiving area of the solar cell is enlarged and contact resistance is improved to thus increase short-circuit current (Isc), thereby increasing the power generation efficiency of the solar cell.

Moreover, the conductive paste according to the present invention may be applied to crystalline solar cells (P-type, N-type), PESC (Passivated Emitter Solar Cell), PERC (Passivated Emitter and Rear Cell), and PERL (Passivated Emitter Real Locally Diffused) structures, and also to modified printing processes such as double printing, dual printing, etc.

### EXAMPLES AND COMPARATIVE EXAMPLES

A glass frit having the composition shown in Table 1 below and having the properties shown in Table 2 below was prepared, and a binder, a dispersant, a leveling agent and the glass frit were added in the amounts shown in Table 3 below into a mixer, dispersed using a three-roll mill, mixed with a silver powder, further dispersed using a three-roll mill, and then defoamed under reduced pressure to afford a conductive paste.

TABLE 1

| Component | Glass | Glass | Glass | Glass |
|---|---|---|---|---|
| (amount: mol %) | frit A | frit B | frit C | frit D |
| PbO | 25 | 26 | 35 | 31 |
| TeO₂ | 32 | 32 | 52.5 | 35 |
| Bi₂O₃ | 17 | 15 | | 25 |
| SiO₂ | 5 | 10 | | |
| Li₂O | 7 | 5 | 7 | 6 |
| Na₂O | 6 | 5 | 2 | 3 |
| K₂O | 6 | 5 | | |
| ZnO | 1 | 1 | | |
| Al₂O₃ | 1 | | | |
| TiO₂ | | 1 | 1.5 | |
| Total | 100 | 100 | 100 | 100 |

TABLE 2

| | Glass | Glass | Glass | Glass |
|---|---|---|---|---|
| Properties | frit A | frit B | frit C | frit D |
| Tg (° C.) | 268 | 260 | 260 | 265 |
| D50 (μm) | 2.1 | 2.18 | 2.06 | 2.12 |

TABLE 3

| Component | | | Comparative | Comparative |
|---|---|---|---|---|
| (amount: g) | Example 1 | Example 2 | Example 1 | Example 2 |
| EC | 0.5 | 0.5 | 0.5 | 0.5 |
| EFKA-4330 | 0.5 | 0.5 | 0.5 | 0.5 |
| BYK180 | 0.7 | 0.7 | 0.7 | 0.7 |
| Texanol | 2.5 | 2.5 | 2.5 | 2.5 |
| Butyl | 2.5 | 2.5 | 2.5 | 2.5 |
| cellosolve | | | | |
| Thixatrol ST | 0.3 | 0.3 | 0.3 | 0.3 |
| Dimethyl | 1.5 | 1.5 | 1.5 | 1.5 |
| adipate | | | | |
| Silver powder | 89.5 | 89.5 | 89.5 | 89.5 |
| Glass frit A | 2 | | | |
| Glass frit B | | 2 | | |
| Glass frit C | | | 2 | |
| Glass frit D | | | | 2 |

### TEST EXAMPLES

(1) Measurement of Wetting Diameter Ratio and Aspect Ratio

A pellet having a diameter of 6.8 mm and a depth of 2 mm was made using the glass frit prepared above, placed on a wafer, and sintered at a temperature of 500 to 900° C. for 20 sec to 30 sec, after which the diameter thereof was measured, thereby calculating a wetting diameter ratio (%) using the following Equation 1 and an aspect ratio after firing using the following Equation 2. The results of measurement of diameter and height are shown in Table 4 below.

Wetting diameter ratio (%)=(diameter after sintering/diameter before sintering)*100 [Equation 1]

Aspect ratio=height of pellet from wafer/diameter of pellet [Equation 2]

TABLE 4

| | | Glass | Glass | Glass | Glass |
|---|---|---|---|---|---|
| | | frit A | frit B | frit C | frit D |
| Diameter (mm) | Before firing | 6.8 | 6.8 | 6.8 | 6.8 |
| | After firing | 11.39 | 10.74 | 15.44 | 8.8 |
| Wetting diameter ratio (%) | | 167.5 | 158 | 227 | 129 |
| Height (mm) | Before firing | 2 | 2 | 2 | 2 |
| | After firing | 1.88 | 1.84 | 0.48 | 1.14 |

| | | | | |
|---|---|---|---|---|
| Aspect ratio (After firing) | 0.165 | 0.171 | 0.031 | 0.130 |

As is apparent from Table 4, when the glass frit having the composition according to the present invention was fired, the diameter increase after firing was 167.5% and 158%, which meet the criterion of 180% or less. The spreadability can be seen to be remarkably improved compared to 227%, which is the diameter increase after firing in Comparative Example 1, in which the amounts of PbO and TeO₂ were high. In Comparative Example 2, in which the amounts of PbO and TeO₂ were slightly decreased and Bi₂O₃ was added in excess compared to Examples of the present invention, the spreadability was improved but the aspect ratio was lowered, from which it can be seen that the series resistance (Rs) is increased and the power generation efficiency (Eff) of the solar cell is thus deteriorated, as shown in the results of measurement of solar cell characteristics described later.

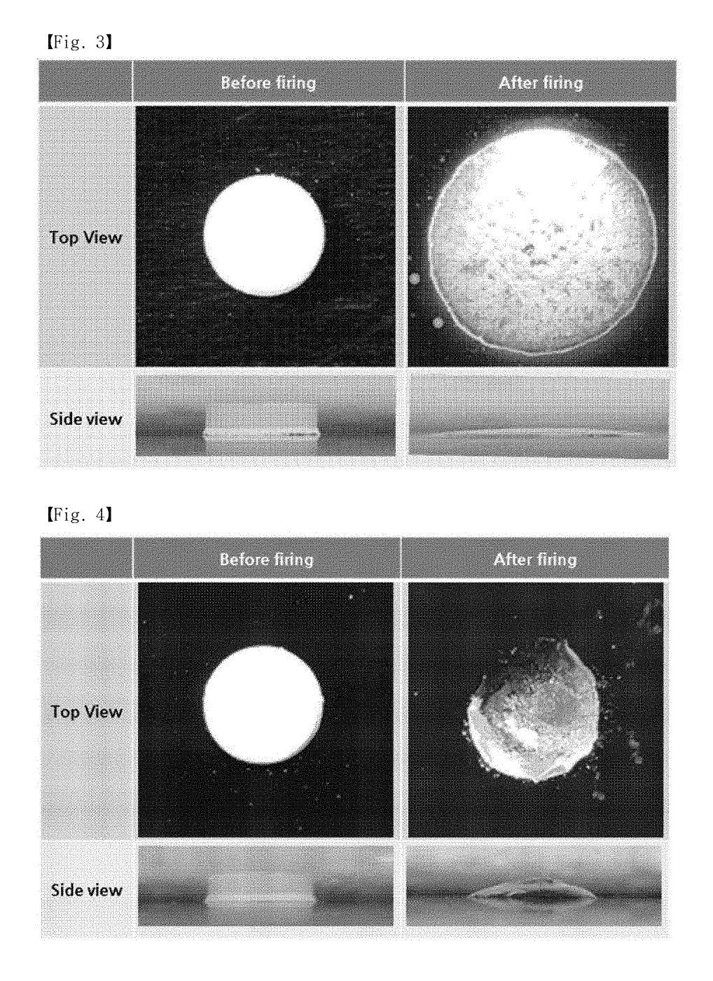

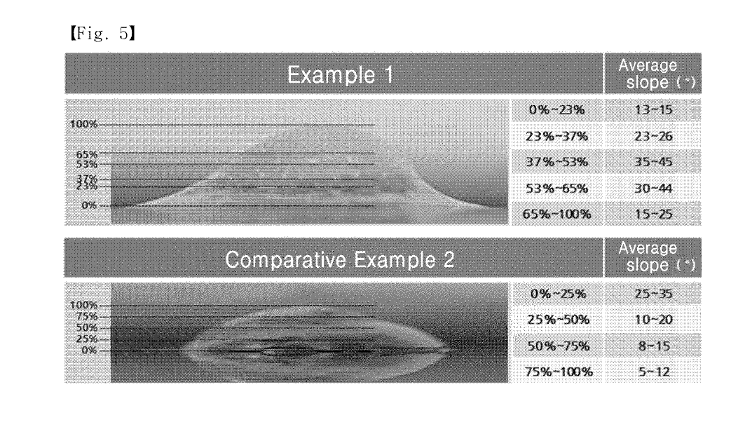

FIG. 2 shows the image before firing and the image after firing of the pellet of Example 1, FIG. 3 shows the image before firing and the image after firing of the pellet of Comparative Example 1, and FIG. 4 shows the image before firing and the image after firing of the pellet of Comparative Example 2.

As illustrated in the side images after firing of FIGS. 2 to 4, the spreading shape of the pellet upon firing the conductive paste including the glass frit having the composition according to the present invention was also varied. FIG. 5 shows the slope of the tangent line of the pellet surface measured depending on a height relative to the wafer when the height of the pellet after firing in Example 1 and Comparative Example 2 is 100%.

As shown in FIG. 5, the spreading shape of the pellet after firing in Example 1 is configured in the range from a 0% position to a 100% position to include a concave section (0% to 37%) where the slope of the tangent line increases, an inflection section (37% to 65%) where the slope of the tangent line increases and then decreases, and a convex section (65% to 100%) where the slope of the tangent line decreases, whereas Comparative Example 2 has a shape configured to include only a convex section (0% to 100%) where the slope of the tangent line continuously decreases in the range from the 0% position to the 100% position.

As shown in FIG. 5, the pellet after firing in Example 1 has a shape configured such that the average slope increases and then decreases, in which an average slope in the concave section is 13 to 15° and 23 to 26°, an average slope in the inflection section is 30 to 45°, and an average slope in the convex section is 15 to 25°. In contrast, Comparative Example 2 can be seen to have a shape in which the average slope of the tangent line decreases continuously, such as 25 to 35°, 10 to 20°, 8 to 15°, and 5 to 12°, as the position becomes higher when the convex section is divided into 4 equal parts.

The present invention is capable of providing a glass frit having the composition above so as to have the side shape described above, thus improving the wetting characteristics (i.e. contact resistance) by enlarging the area of a portion close to the wafer and improving series resistance by lowering spreadability at a portion far from the wafer, ultimately increasing the conversion efficiency of the manufactured solar cell.

(2) Measurement of Solar Cell Characteristics

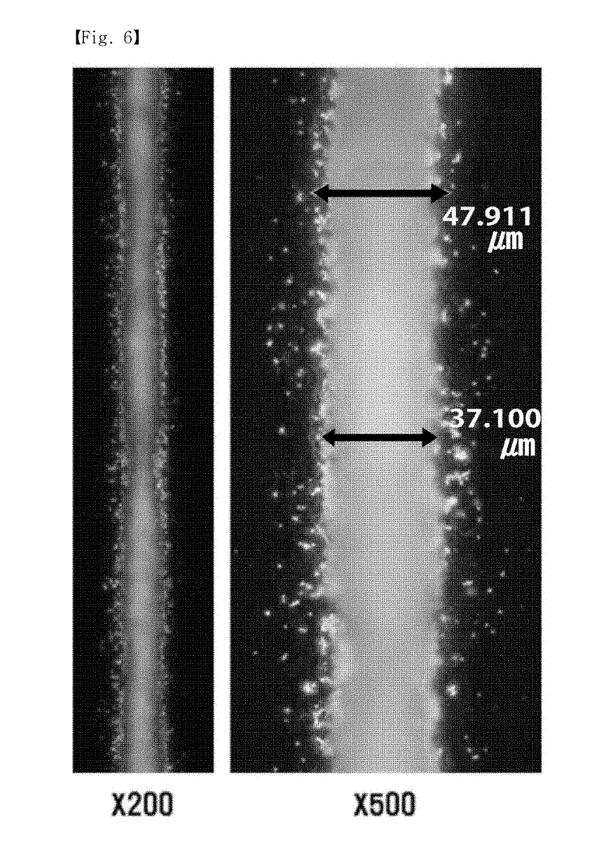

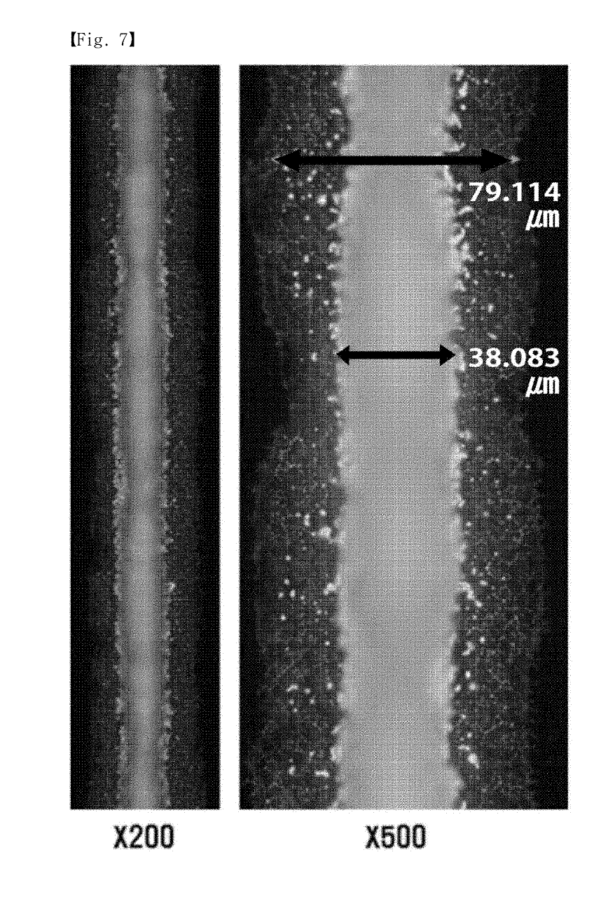

First, an aluminum paste was printed on the rear surface of the wafer and dried at 200 to 350° C. for 20 to 30 sec using a belt-type drying furnace. Then, the conductive paste prepared in the above Examples and Comparative Examples was pattern-printed on the front surface of the wafer through a screen-printing process using a plate having a line width of 36 μm and fired at 500 to 900° C. for 20 to 30 sec using a belt-type firing furnace. The cell thus manufactured was measured for Isc, Voc, Eff, FF, and Rs using a solar cell efficiency measurement device (cetisPV-Celltest 3, made by Halm). The results are shown in Table 5 below, and the line width after firing is shown in FIGS. 6 to 8.

As shown in the electrode images of Example 1 of FIG. 6, the line width inside the electrode was about 37.100 μm, which is evaluated to be optimal compared to Comparative Examples, and the line width outside the electrode was about 47.911 μm, from which bleeding is also evaluated to be optimal.

As shown in the electrode images of Comparative Example 1 of FIG. 7, the line width inside the electrode was about 38.083 μm, and the line width outside the electrode was about 79.114 μm, from which bleeding is also evaluated to be very large. As is apparent from Table 5 below, it can be seen that short-circuit current (Isc) is considerably low.

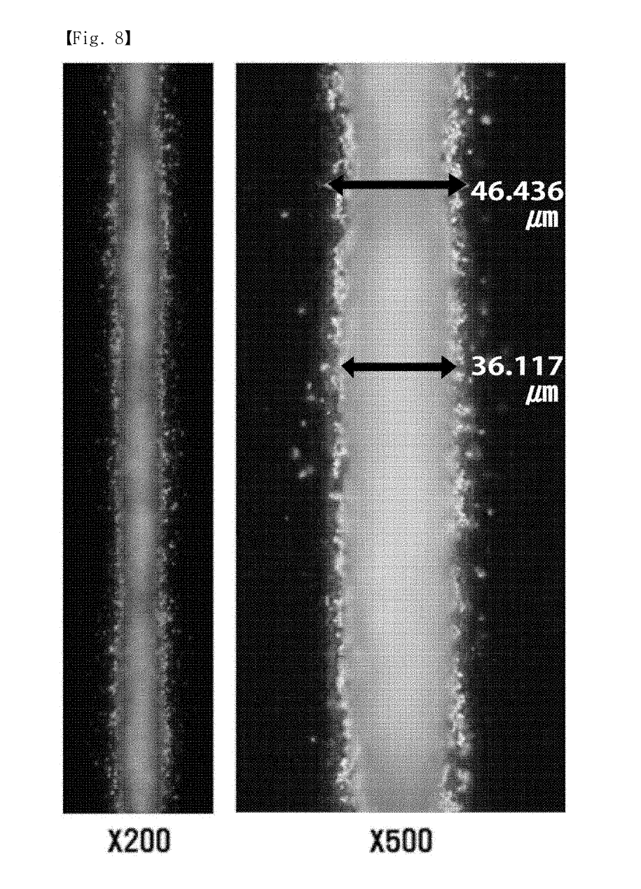

As shown in the electrode images of Comparative Example 2 of FIG. 8, the line width inside the electrode was about 36.117 μm, and the line width outside the electrode was about 46.416 μm, from which bleeding is also evaluated to be very small but contact resistance was poor. As is apparent from Table 5 below, it can be seen that FF (fill-factor) characteristics are poor and the efficiency is the lowest.

TABLE 5

| | | | Comparative | Comparative |
|---|---|---|---|---|
| | Example 1 | Example 2 | Example 1 | Example 2 |
| Isc (A) | 9.416 | 9.418 | 9.395 | 9.421 |
| Voc (V) | 0.6383 | 0.6384 | 0.6381 | 0.6385 |
| Eff (%) | 19.761 | 19.758 | 19.717 | 19.647 |
| FF (%) | 78.635 | 78.59 | 78.651 | 78.05 |
| Rs (mΩ) | 1.625 | 1.628 | 1.612 | 1.737 |

As shown in Table 5, both the short-circuit current and the series resistance of the electrode formed of the conductive paste including the glass frit having the composition according to the present invention were improved, and thus the conversion efficiency (Eff) of the solar cell of Examples was higher than Comparative Examples.

Given that the efficiency of a solar cell is measured in 0.05% increments and an increase in efficiency of 0.05% is very meaningful, as shown in Table 5, in the solar cell including the electrode made of the conductive paste including the glass frit having the composition according to the present invention, the electrode line width and bleeding are smaller than those of Comparative Example 1, thus exhibiting high short-circuit current, and moreover, series resistance, that is, contact resistance, is superior to that of Comparative Example 2, whereby FF is high. Therefore, the solar cell of the present invention can be concluded to exhibit high conversion efficiency compared to Comparative Examples 1 and 2 to thus increase the power generation efficiency of the solar cell.

The features, structures, effects and so on illustrated in the individual exemplary embodiments above may be combined or modified with other exemplary embodiments by those skilled in the art. Therefore, content related to such combinations or modifications should be understood to fall within the scope of the present invention.

1. A conductive paste composition for a solar cell electrode using a glass frit, the conductive paste composition comprising a conductive metal powder, a glass frit and an organic vehicle,
wherein, when a pellet having a diameter of 6.8 mm and a depth of 2 mm is made using the glass frit, placed on a wafer and sintered at a temperature of 500 to 900° C. for 20 to 30 sec, a wetting diameter ratio calculated using Equation 1 below is 180% or less.
Wetting diameter ratio (%)=(diameter after sintering/diameter before sintering)*100 [Equation 1]

2. A conductive paste composition for a solar cell electrode, comprising a conductive metal powder, a glass frit and an organic vehicle,
wherein, when a pellet having a diameter of 6.8 mm and a depth of 2 mm is made using the glass frit, placed on a wafer and sintered at a temperature of 500 to 900° C. for 20 to 30 sec, an aspect ratio calculated using Equation 2 below is 0.15 or more.
Aspect ratio=height of pellet from wafer/diameter of pellet [Equation 2]

3. A conductive paste composition for a solar cell electrode, comprising a conductive metal powder, a glass frit and an organic vehicle,
wherein a pellet having a diameter of 6.8 mm and a depth of 2 mm is made using the glass frit, placed on a wafer and sintered at a temperature of 500 to 900° C. for 20 to 30 sec, and when a side shape of the sintered pellet is represented as a slope of a tangent line of a pellet surface to the wafer depending on a height relative to the wafer, the sintered pellet shows a side shape having a concave section where the slope of the tangent line increases, an inflection section where the slope of the tangent line increases and then decreases, and a convex section where the slope of the tangent line decreases with an increase in the height relative to the wafer.

4. The conductive paste composition of claim 3, wherein, when a position of the sintered pellet depending on the height from the wafer is set to a range from 0% to 100%, the concave section is formed at a 0% to 40% position, the inflection section is formed at a 30% to 70% position, and the convex section is formed at a 70% to 100% position.

5. The conductive paste composition of claim 3, wherein an average slope of the tangent line in the concave section is 10 to 30°, an average slope of the tangent line in the inflection section is 30 to 50°, and an average slope of the tangent line in the convex section is 10 to 30°.

6. A conductive paste composition for a solar cell electrode, comprising a conductive metal powder, a glass frit and an organic vehicle,
wherein the glass frit contains lead (Pb) and tellurium (Te), in which 15 to 29 mol % of PbO and 15 to 34 mol % of TeO2 are contained on an oxide basis.

7. The conductive paste composition of claim 6, wherein the glass frit further contains bismuth (Bi), in which 10 to 24 mol % of Bi2O3 is contained on an oxide basis.

8. The conductive paste composition of claim 7, wherein the glass frit further contains an alkali metal including lithium (Li), sodium (Na) and potassium (K), in which 3 to 12 mol % of Li2O, 3 to 10 mol % of Na2O and 3 to 10 mol % of K2O are contained on an oxide basis.

9. The conductive paste composition of claim 8, wherein the glass frit further contains silicon (Si), in which 20 mol % or less of SiO2 is contained on an oxide basis.

10. The conductive paste composition of claim 9, wherein the glass frit further contains at least one selected from the group consisting of zinc (Zn), aluminum (Al) and titanium (Ti), in which 5 mol % or less of ZnO, 5 mol % or less of Al2O3, and 5 mol % or less of TiO2 are contained on an oxide basis.

11. The conductive paste composition of claim 6, wherein the glass frit has a glass transition temperature (Tg) of 200 to 300° C.

12. The conductive paste composition of claim 6, wherein the glass frit has an average particle diameter of 0.5 to 10 μm.

13. The conductive paste composition of claim 6, comprising, based on a total weight of the composition:
70 to 98 wt % of the conductive metal powder,
1 to 15 wt % of the glass frit, and
1 to 20 wt % of the organic vehicle.

14. A solar cell, comprising a front electrode provided on a substrate and a rear electrode provided under the substrate,
wherein the front electrode is manufactured by applying, drying and firing the conductive paste composition of claim 1.
